(19) United States
(12) Patent Application Publication
(10) Pub. No.: US 2012/0261804 A1
(43) Pub. Date: Oct. 18, 2012

(54) VERTICAL SUBSTRATE DIODE, METHOD OF MANUFACTURE AND DESIGN STRUCTURE

(75) Inventors: Junjun Li, Williston, VT (US); Zhengwen Li, Danbury, CT (US); Chengwen Pei, Danbury, CT (US); Jian Yu, Danbury, CT (US)

(73) Assignee: INTERNATIONAL BUSINESS MACHINES CORPORATION, Armonk, NY (US)

(21) Appl. No.: 13/087,915

(22) Filed: Apr. 15, 2011

(51) Int. Cl. H01L 29/06; H01L 21/22; B82Y 99/00

(52) U.S. Cl. 257/653; 438/510; 977/762; 257/E29.022; 257/E21.135

(57) ABSTRACT

A diode structure, formed under a buried dielectric layer of a silicon on insulator (SOI), method of manufacturing the same and design structure thereof are provided. In an embodiment the p-n junction of the diode structure can be advantageously arranged in a vertical orientation. The cathode comprises an N+ epitaxial layer formed upon a P-type substrate. The anode comprises an active region of the P-substrate. Contacts to the cathode and anode are formed through the buried dielectric layer. Contact to the anode is accomplished via a deep trench filled with a conductive plug. The deep trench also provides electrical isolation for the cathode (as well as p-n junction). Advantageously, embodiments of the present invention may be formed during formation of other structures which also include trenches (for example, deep trench capacitors) in order to reduce process steps required to form the diode structure under the buried dielectric layer of the SOI substrate.

### BACKGROUND

### FIELD OF THE INVENTION

The present invention relates to vertical diodes, and more particularly, to vertical diodes formed under a buried dielectric layer of a silicon on insulator (SOI), method of manufacturing the same and design structure thereof.

One of the common trends in the electronics industry is the miniaturization of electronic devices. This trend is especially true for electronic devices operated through the use of semiconductor chips. One common type of electronic device found on a microchip is a diode. A diode is a two-terminal electronic component that conducts electric current in only one direction. A diode functions as a type of electrical gate or switch, it allows an electric current to pass in one direction while blocking current in the opposite direction.

Conventional diodes are typically formed from a silicon material that is modified through a doping process. Doping is a process in which ions are implanted within silicon. There are two general types of dopants: P-type dopants and N-type dopants. P-type dopants are materials that when implanted within the silicon produce regions referred to as holes. These holes can freely accept electrons. In contrast, N-type dopants are materials that when implanted within silicon produce extra electrons. The extra electrons are not tightly bound and thus can easily travel through the silicon. In general, a diode is formed when a material doped with a P-type dopant is in contact with a material doped with an N-type dopant.

ESD diodes are special diodes well known in present day semiconductor technology in order to protect Input/Output (I/O) and other internal circuitry from electrostatic discharges (ESD) and other overvoltage conditions that could cause catastrophic failure in integrated circuits. Because of high sheet resistance, these ESD diodes, typically, must be made large in order to discharge the ESD currents. Such structures are very expensive from a production standpoint because of fairly large total surface area consumed by the ESD device.

Accordingly, it is desirable to provide diode structures and method for fabricating those diode structures with reduced utilized silicon area.

### SUMMARY

In an aspect of the invention, a diode structure comprises a first active region defined in a silicon substrate and a second active region defined in an epitaxial layer grown on the silicon substrate. The first active region may be formed by doping a first type of impurity, and the second active region may be formed by doping a second type of impurity. The first active region in contact with the second active region comprises a junction of the diode structure formed below a buried dielectric layer overlying the epitaxial layer. The diode structure further comprises a trench structure formed through the buried dielectric layer, the epitaxial layer, and extending into the underlying silicon substrate. The trench structure surrounds the second active region and defines a sidewall boundary of the second active region, and the buried dielectric layer defines an upper boundary of the second active region.

In another aspect of the invention, a method for fabricating a diode structure comprises providing a SOI substrate. The SOI substrate comprises a silicon substrate layer, an epitaxial layer overlying the silicon substrate, an upper silicon layer and a buried dielectric layer between the epitaxial layer and the upper silicon layer. A second active region may be formed by doping the epitaxial layer with a second type of impurity. The method further comprises forming a trench structure around the second active region. The trench structure extends through the upper silicon layer, the buried dielectric layer, and the epitaxial layer. A bottom of the trench structure is located in the underlying silicon substrate. The trench structure defines a sidewall boundary of the second active region and the buried dielectric layer defines an upper boundary of the second active region. The method further comprises forming a first active region in the silicon substrate within a region bounded by the trench structure and below the second active region. The method further comprises filling the trench structure with a conductive plug after placing a filler structure on sidewalls and the bottom of the trench structure. The first active region in contact with the second active region comprises a junction of the diode structure formed below the buried dielectric layer.

In another aspect of the invention, a design structure embodied in a machine readable medium for designing, manufacturing, or testing an integrated circuit is provided. The design structure comprises the structures and/or methods of the present invention.

A more complete understanding of the present invention, as well as further features and advantages of the present invention, will be obtained by reference to the following detailed description and drawings. It is to be understood that both the foregoing general description and the following detailed description are exemplary and explanatory only, and should not be considered restrictive of the scope of the invention, as described and claimed. Further, features or variations may be provided in addition to those set forth herein. For example, embodiments of the invention may be directed to various combinations and sub-combinations of the features described in the detailed description.

### BRIEF DESCRIPTION OF THE SEVERAL VIEWS OF THE DRAWINGS

The present invention is described in the detailed description which follows in reference to the noted plurality of drawings by way of non-limiting examples of exemplary embodiments of the present invention.

FIGS. 1 through 8B schematically illustrate method steps for fabrication of a diode structure in accordance with an embodiment of the disclosure, wherein FIGS. 1 through 6A, 7, and 8A are cross section views and FIGS. 6B and 8B are top views illustrating such method steps;

FIG. 9 illustrates a top view of a diode structure in accordance with another embodiment of the present invention;

FIG. 10 illustrates a section view of a diode structure in accordance with yet another embodiment of the present invention; and

FIG. 11 is a flow diagram of a design process used in semiconductor design, manufacture, and/or test.

### DETAILED DESCRIPTION

The present invention relates to a structure and method of forming a diode under a buried dielectric layer of a SOI substrate. More specifically, the present invention comprises a diode structure having a first active region defined in a semiconductor substrate and a second active region defined in an epitaxial layer grown on the semiconductor substrate. The first active region may be formed by doping a first type of impurity, and the second active region may be formed by doping the second type of impurity. The first active region in contact with the second active region comprises a junction of the diode structure formed below a buried dielectric layer overlying the epitaxial layer. The diode structure further comprises a trench structure formed through the buried dielectric layer, the epitaxial layer, and extending into the underlying silicon substrate. The trench structure defines a sidewall boundary of the second active region and the buried dielectric layer defines an upper boundary of the second active region. Advantageously, the present invention may be formed during formation of other structures which also include trenches, for example, but not limited to, deep trench capacitors, in order to reduce process steps required to form the diode structure.

In embodiments, vertical orientation of a diode structure provides extended ability for dimensional scaling. Since the diode has a vertical formation and the structure is formed under a buried dielectric layer, use of the surface area on the silicon microchip is significantly reduced. ESD protection for microprocessors has proven to be a challenging issue. The structure of the present invention is an improvement over prior art as it allows one to create a vertical structure which provides lower resistance for ESD discharging current. Another advantage of the present invention is that the diode structure disclosed herein improves the current crowding effect for discharging current. Current crowding is a non-homogeneous distribution of current density, especially at the vicinity of the PN junctions. Current crowding is one of the limiting factors of efficiency of diodes. In accordance with one disclosed embodiment of the invention, the diode may be used for, for example, but not limited to, all ESD diodes connected between Input/Output (I/O) signal pads and ground pads.

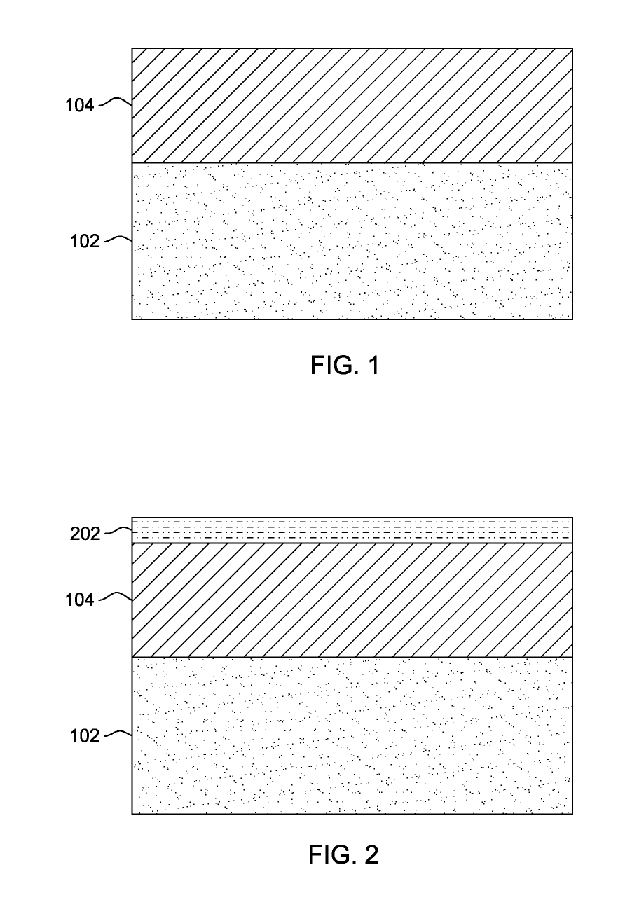

FIGS. 1 through 8B schematically illustrate method steps for fabrication of a diode structure in accordance with an embodiment of the invention. For convenience, when the discussion of the fabrication steps of the present invention refers to a particular type of substrate and/or particular type of dopant impurities, it is understood that the present invention is applicable to the opposite type without departing from the spirit of the present invention. For instance, when reference is made to a p-type silicon substrate as the semiconductive substrate and n-type impurities as diffused or implanted dopant impurity, it is understood that an n-type substrate and p-type diffused or implanted dopant impurities are likewise suitable. In addition, it is understood that when the discussion refers to n-type impurities, the process steps are applicable to p-type impurities and vice versa. Also, when reference is made to impurities of a “first type” and to impurities of a “second type,” it is understood that the “first type” refers to an n-type or p-type impurities and “second type” refers to the opposite conductivity type. That is, if the “first type” is p, then the “second type” is n. If the “first type” is n, then the “second type” is p. However, once a convention is selected for manufacturing of a diode, the convention must be maintained. That is, either all first type dopants must be N doped and all second type dopants P doped, or all first type dopants must be P doped and all second type dopants N doped.

Referring to FIG. 1, the method in accordance with this exemplary embodiment of the invention begins with providing a semiconductor layer 102 of the SOI structure. Semiconductor layer 102 comprises a conventional silicon wafer. Preferably, the initial wafer is a single crystal silicon wafer.

Still referring to FIG. 1, an epitaxial layer 104 may be deposited or grown on top of the semiconductor layer 102 by means known in the art. For example, epitaxial layer 104 may be grown at 1000° C. Epitaxial layer 104 may be doped in-situ with a second type dopant. Alternatively, as previously discussed, the epitaxial layer 104 may consist of first type dopant material, while semiconductor layer 102 may be doped with the second type of dopant. In-situ doping refers to the doping technique wherein the dopants are introduced to the epitaxial layer 104 at the same time the epitaxial layer 104 is being deposited or grown. In situ doping is attractive because the dopant distribution is uniform throughout the layer if the dopant is incorporated during and along with the deposition or growth of epitaxial layer 104. Epitaxial layer 104 may be, for example, 3 to 5 microns thick with a doping concentration within a range of about 1×10¹⁹ atoms per cm³ to about 1×10²⁰ atoms per cm³.

Once epitaxial layer 104 is obtained, an insulation layer 202 is formed so as to cover epitaxial layer 104. Dielectric layer 202, as shown in FIG. 2, is preferably silicon dioxide (SiO₂) formed through a deposition oxidation process. Dielectric layer 202 is commonly referred to as a buried oxide or “BOX” layer and will so be referred herein. Dielectric layer 202 may be deposited to a thickness of about 5-200 nm.

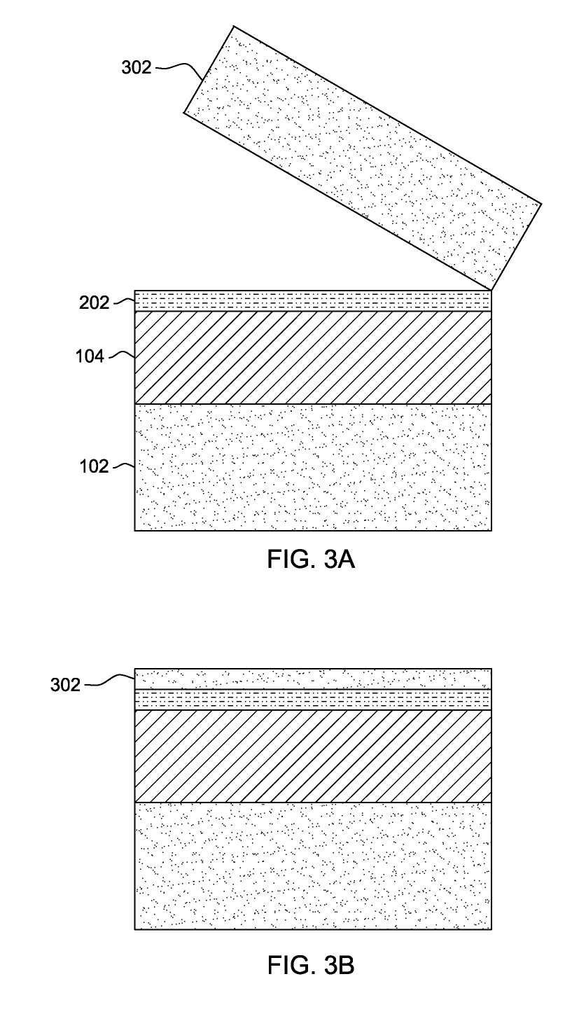

After that, the silicon active layer of the SOI wafer may be formed by bonding upper silicon layer 302 to the dielectric layer 202, as shown in FIG. 3A. Bonding is generally performed in two stages. In a first stage, the substrates are heated to approximately 600° C., in an inert environment for approximately three hours. The heating of the first stage causes bonding of the upper silicon layer 302 to the dielectric layer 202 due to Van der Waals forces. In a second stage of the bonding process, the bonded structure is heated to approximately 1050-1200° C. for 30 minutes to two hours to strengthen the bond between the dielectric layer 202 and upper silicon layer 302. The upper silicon layer 302 may then be thinned and polished, for example by chemical mechanical planarization (CMP) techniques, to a thickness of about 5-300 nm, leaving a SOI structure as shown in FIG. 3B. The BOX layer 202 isolates upper silicon layer 302 from semiconductor layer 102 below the BOX layer 202. As shown in FIG. 3B, semiconductor layer 102 is substantially thicker than upper silicon layer 302.

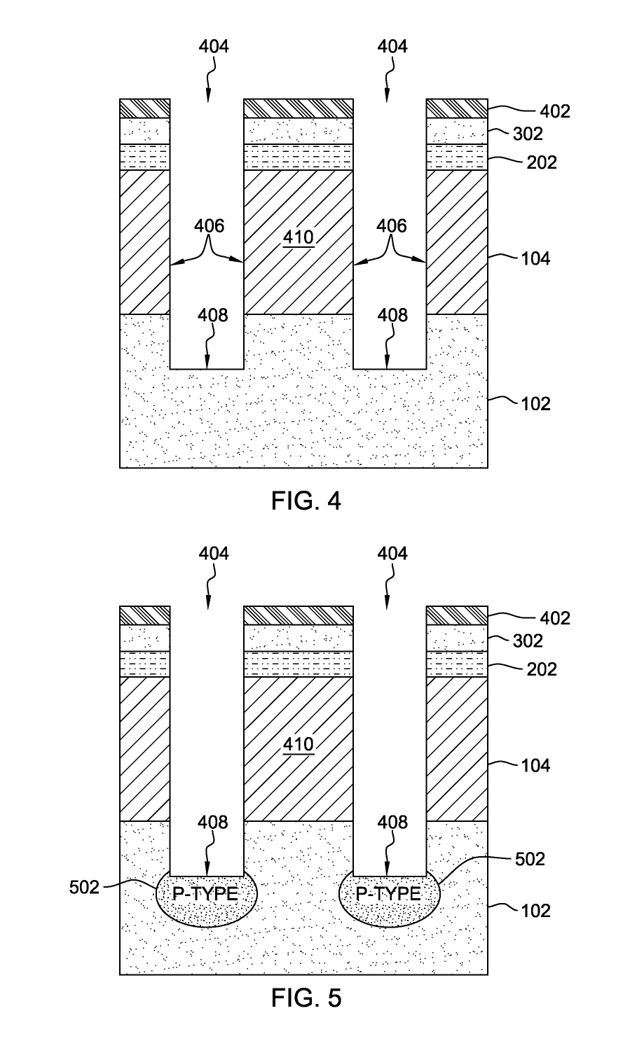

Turning now to FIG. 4, a pad layer 402 of an insulating material such as silicon nitride (SiN) may be formed on the upper surface of silicon layer 302. The pad layer 402 may be formed using, for example, low-pressure chemical vapor deposition (LPCVD) depositing to a thickness of 10 nm to 500 nm, preferably 200 nm. Optionally, prior to forming the pad LPCVD SiN layer 402, a thin (2 nm to 10 nm, preferably 5 nm) thermal oxide layer (not shown) may be formed on the upper silicon layer 302. The next step involves etching trenches 404 within the formed SOI structure. A hard mask layer (not shown) of a suitable masking material such as silicon dioxide may be deposited on pad layer 402 to a thickness of 100 nm to 2000 nm, preferably 1000 nm. The hard mask layer may be patterned using a conventional photolithography technique. Then, deep trenches 404 are defined and partially formed using an anisotropic dry etch technique, such as a Reactive Ion Etch (RIE), etching through pad layer 402, upper silicon layer 302, BOX layer 202, epitaxial layer 104 and partially etching through the silicon substrate 102. Preferably, RIE may be used to etch trenches 404 to their full depth. Deep trench 404 may have a depth of approximately 3 microns. As shown in FIG. 4, the deep trench structure 404 is much deeper than it is wide, having, for example, an aspect ratio (depth to width ratio) of approximately 40:1. Then, the hard mask may be removed, preferably, using a hydrofluoric acid solution. FIG. 4 shows resultant isolation trenches 404 having sidewalls 406 and a bottom 408. Trenches 404 thus frame second active region 410. In other words, the trench isolation structure 404 defines a sidewall boundary and the BOX layer 202 defines an upper boundary of the second active region 410.

FIG. 5 illustrates a next step in the process. A deep implant may be carried out to form active regions of first type by employing, for example, an ion implantation method. Ion implantation is a low-temperature technique for the introduction of impurities (dopants) into semiconductors and offers more flexibility than diffusion. In ion implantation, dopant atoms are volatilized, ionized, accelerated, separated by the mass-to-charge ratios, and directed at a target that is typically a silicon substrate. The atoms enter the crystal lattice, collide with the host atoms, lose energy, and finally come to rest at some depth within the solid. The average penetration depth can be determined by the dopant, substrate materials, and acceleration energy. For example, if second active region 410 is of type N, the deep implant shown in FIG. 5 will introduce dopants of type P into semiconductor substrate 102 to form P-type active regions 502. An ion implanter may be typically employed for the actual implantation. Implantation may be carried out through bottom 408 of deep trench structure 404 to form the P-type dopant regions 502 below the trenches 404 for good contacts to semiconductor substrate 102, as shown in FIG. 5. In this exemplary embodiment, the deep implant may be carried out using a tilted ion implantation technique. The P-type dopant, such as boron, can be implanted at a dosage, for example, between about 1×10¹⁹ atoms per cm³ and about 1×10²⁰ atoms per cm³ in bulk substrate 102. The tilted implant can have an implant energy of, for example, between about 15 keV and about 30 keV. Alternatively, the deep implant can be carried out by utilizing an implantation mask (not shown).

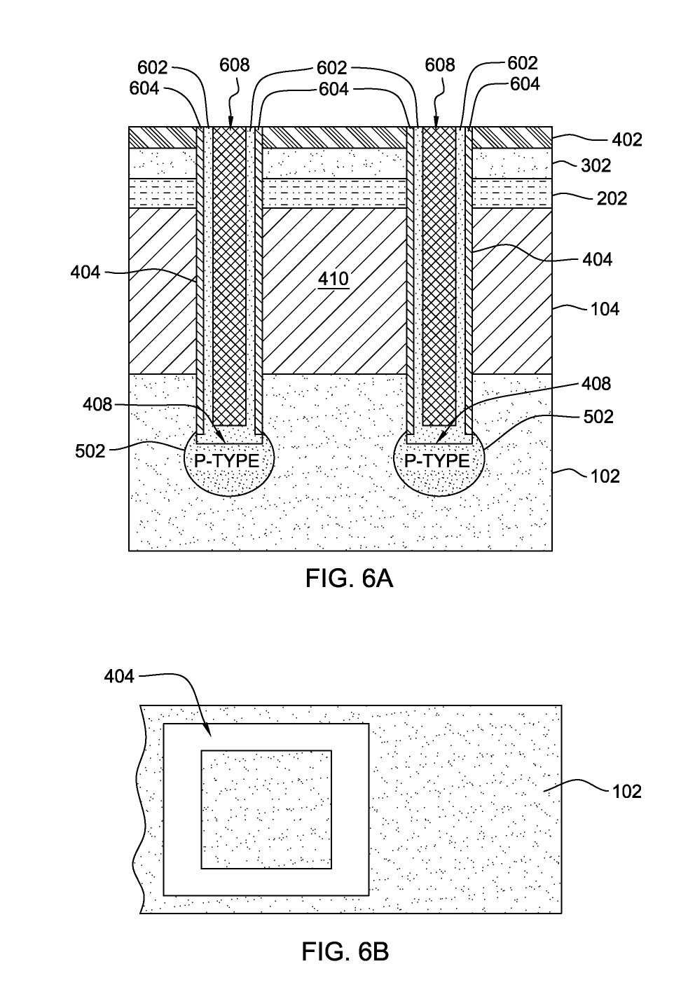

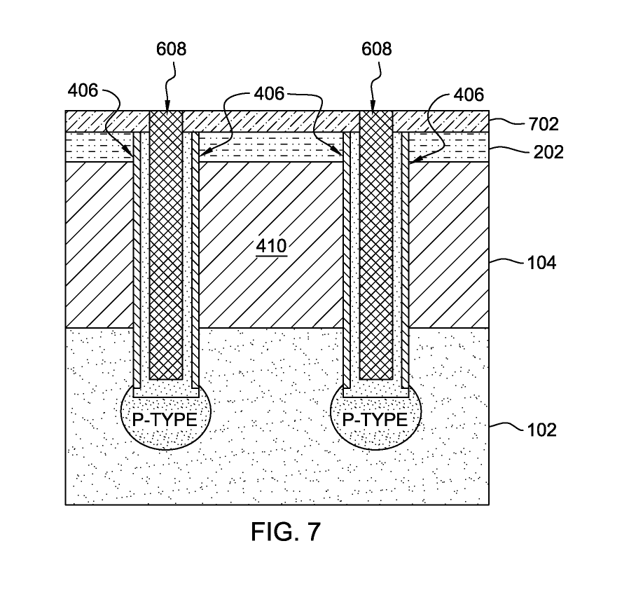

FIG. 6A illustrates a next step in the process of forming the diode structure. A thin conformal layer of high-k dielectric material 604 may be deposited within the trenches 404, having a thickness, for example of about 10 nm. This material, lining the deep trench 404, may be any high-k insulator, for example, but not limited to, hafnium oxide (HfO₂), deposited by atomic layer deposition (ALD). Next, as shown in FIG. 6A, high-k dielectric material 604 may be removed from the bottom of trenches 408 by any convenient method, such as by wet etching, dry etching, and the like. Next, a thin layer of metal 602 may be deposited within the trenches 404. The metal 602 covers high-k dielectric material 604 substantially uniformly on the sidewalls of the deep trench 404. Layer 602 can be made from any metal conductor. Advantageous metals for this purpose are aluminum (Al) or copper (Cu). Suitable deposition processes such as ALD, or MOCVD (metalorganic chemical vapor deposition) may be employed to deposit this material. This step may be followed by a thick deposition of a conductive plug layer 608, for example, but not limited to, doped polysilicon. Doped polysilicon 608 may fill the trench as shown in FIG. 6A. Polysilicon may be doped with first type of dopant (same type of dopant that was implanted into semiconductor substrate 102, as described above in conjunction with FIG. 5). Any suitable deposition process, for example, but not limited to chemical vapor deposition (CVD), may be employed to deposit polysilicon 608. Alternatively, the trench may be filled with any conductive material, including, but not limited to, conductive material used for layer 602. This conductive plug layer 608 along with metal layer 602 will serve as a conductive path between the first active region 502 and the surface of the SOI structure described herein.

At this stage of the process, a trench isolation structure has been formed. This structure may be used to isolate one (or more) diodes from other devices. As shown in FIG. 6B, trench isolation structure 404 may be formed, surrounding the junction between first active region and second active region. Note that the width of trench 404 may be between approximately 90 nm and 500 nm. FIG. 6B shows a top view of the trench isolation structure 404. In this exemplary embodiment, trench structure 404 is shaped as a rectangle. However, the present invention is not so limited, as trench isolation structure may have other shapes, such as circular, oval, square, and the like.

FIG. 7 illustrates a next step in the process of forming the diode structure. This step comprises a conventional shallow trench isolation (STI) process. According to the conventional STI process, the pad nitride layer 402 may be removed by a wet-etching process. Subsequently, the upper silicon layer 302 may be removed by RIE. As shown in FIG. 7, a dielectic layer 702, such as silicon dioxide layer, may be deposited next on top of BOX layer 202 in such a way that it covers the entire structure, including trench walls 406, but leaves conductive plug layer 608 exposed. Silicon dioxide layer 702 may be formed by, for example, a thermal oxidation process, wherein the thickness of the silicon dioxide layer 702 may be between about 5 nm and about 300 nm.

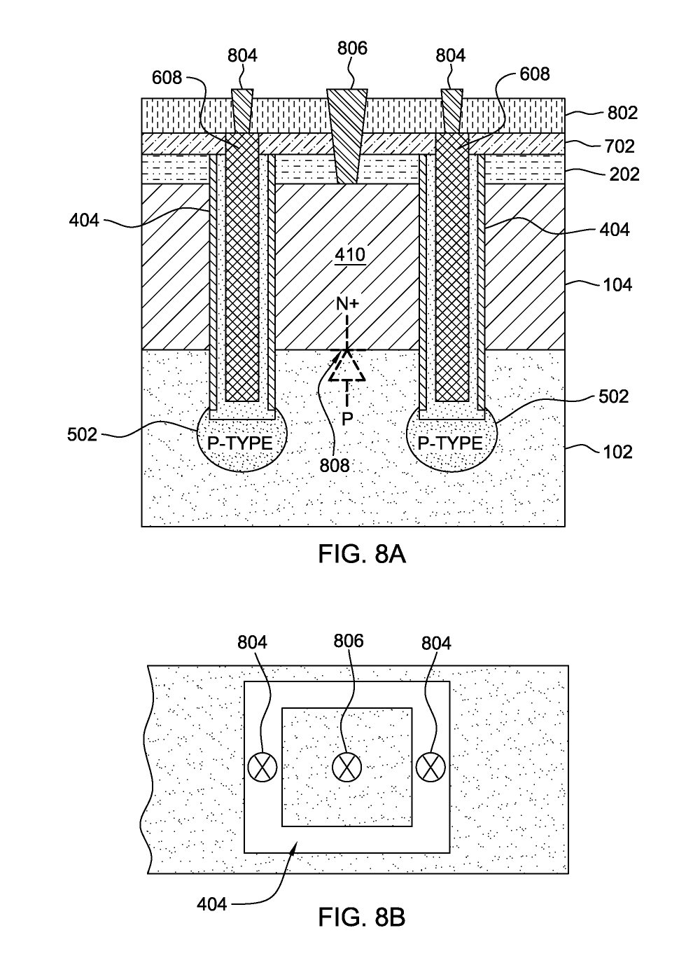

Once silicon dioxide layer 702 is obtained, according to this exemplary embodiment, a top dielectric layer 802 may be formed so as to cover silicon dioxide layer 702 and to cover exposed conductive plug 608, as shown in FIG. 8A. Preferably, the top dielectric layer 802 can be formed of a low-k dielectric material. The low-k dielectric material can be any dielectric material with a dielectric constant lower than that of silicon dioxide (SiO₂). The top dielectric layer 802 can be formed using the CVD method or ALD method and is preferably formed at a temperature 500° C. with a thickness of about 200 nm. An exemplary embodiment may also include providing contacts upon the top dielectric layer 802 by etching openings, such as contact vias, using a pattern for contacts. Etching contact vias may include etching down to conductive plug layer 608 that fills isolation structures 404 for anode contacts. Etching contact vias may also include etching through the top dielectric layer 802, through the dioxide layer 702 and through the dielectric layer 202 down to second active region 410. The exemplary embodiment may also include depositing conductive material into the vias to form a plurality of anode contacts 804 and at least one cathode contact 806. The conductive material may include a material such as a metal, a metal alloy, a silicide, a conductive metal nitride, a conductive metal oxide, silicon, or the like or combinations thereof.

At this stage of the process, a vertical diode structure has been formed, comprising at least one anode (first active region of a first conductivity type) 502 and at least one cathode (second active region of a second conductivity type) 410. The diode structure also comprises a plurality of electrical contacts to anodes 804 (through the conductive plug 608) and cathodes 806. The p-n junction 808 of the diode structure has a vertical orientation and is formed under the BOX layer 202 by an overlap and contact between first active region 502 and second active region 410. Furthermore, according to the exemplary embodiment of the present invention, the diode structure also includes trench isolation structure 404, such that the p-n junction 808 is bounded by the isolation structure 404, as shown in FIG. 8B. FIG. 8B is a top view and depicts cathode contact 806. It will be apparent to a person of ordinary skill in the art that p-n junction region 808 is formed underneath cathode contact 806 and underneath the BOX layer 202 of the SOI structure. As previously indicated, trench isolation structures 404 of different shapes may be employed in various embodiments. It must be noted that second active region 410 is bounded by the trench isolation structure 404 and BOX layer 202.

One feature of the invention is that this formed diode structure shown in FIG. 8A is entirely compatible with the steps used to form embedded Dynamic Random Access Memory (eDRAM) devices. For example, trench isolation structures 404 can be formed at the same time as deep trenches are formed for eDRAM capacitors. Therefore, according to one practical aspect of the present invention, steps described above in conjunction with FIGS. 1 through 8A would be performed simultaneously with the steps of forming eDRAM devices to minimize process complexity and expense.

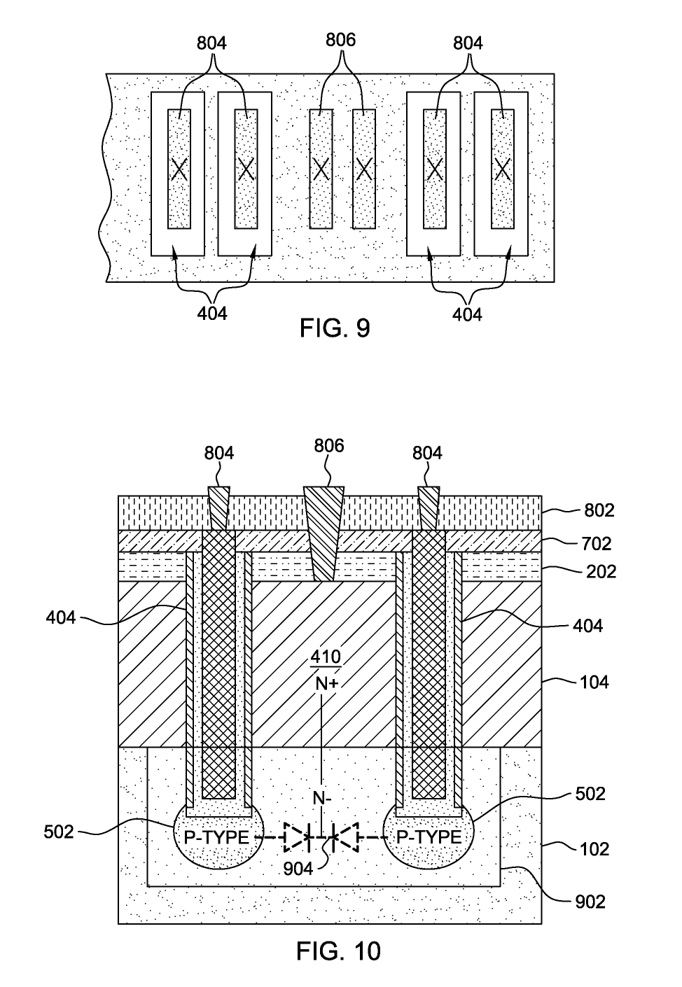

FIG. 9 illustrates another embodiment of the present invention. In FIG. 9, reference numerals that are the same as those used in FIGS. 1-8A refer to structures that are the same as those depicted and described with reference to FIGS. 1-8A. FIG. 9 shows a top view of an alternative diode structure. In this exemplary embodiment, the p-n junction area is not surrounded by isolation structure 404 having ring-shaped geometry. Instead, this embodiment contemplates one or more p-n junction areas that are formed in substantially parallel alignment between a plurality of isolation structures 404 on either side of p-n junction regions 808. FIG. 9 is a top view and depicts cathode contacts 806. It will be apparent to a person of ordinary skill in the art that p-n junction regions 808 are formed underneath those cathode contacts 806. Furthermore, according to this embodiment, a plurality of trench isolation structures 404 can be formed in substantially parallel alignment to each other. Trench isolation structures 404 can also be arranged substantially in parallel to p-n junction regions 808 on each side of those regions. However, this invention is not limited to the geometric arrangement depicted in FIG. 9. Various other modifications may be made to the structures of the invention without departing from the spirit and scope of the invention as described and claimed.

FIG. 10 illustrates yet another embodiment of the present invention. In FIG. 10, reference numerals that are the same as those used in FIGS. 1-8A refer to structures that are the same as those depicted and described with reference to FIGS. 1-8A. In the interests of simplifying the description, specific types of dopant conductivity types will be identified. As previously indicated, different dopant conductivity types may be substituted for the specific ones described herein without departing from the scope of the present invention. FIG. 10 shows the addition of n-well region 902. As a practical matter this structure would be formed by adding an additional step to the steps described above in conjunction with FIGS. 1 through 8A. This additional step may require the use of an extra photolithographic implant mask. The implant mask may be used to form the deep n-well region 902 around first active regions 502 by implanting n-type impurities (second type), for example, but not limited to, phosphorus or arsenic, into substrate 102. In this embodiment, N-well 902 results from a phosphorus implant having a dose in a dose range of about 1×10¹² atoms per cm³ to about 1×10¹⁵ atoms per cm³ and an energy in a range between about 25 keV and about 100 keV. It must be noted that the well region 902 should be doped with the dopant having same polarity (N) but lower dopant concentrations (N−) as the second type of dopant (N+) of the second active region 410. According to this embodiment, a lateral p-n junction 904 may be formed by the first active region (P-type) 502 and the n-well region 902. First active region 502 (P-type) still serves as anode and second active region 410 serves as cathode in this structure. The advantage of this structure is that it provides a different current discharging path. More specifically, the diode structure shown in FIG. 10, unlike the structure shown in FIG. 8A, may provide a current discharging path between any combination of pads due to the lateral junction 904 of the P-type impurity region 502 and the N-well region 902 that is isolated from the substrate 102.

Thus, as described above, the present invention relates to a structure and a method of forming a diode comprising an anode and cathode both formed under the BOX layer 202 of a SOI substrate. In an embodiment the p-n junction 808 of the diode can be advantageously arranged in a vertical orientation. The cathode may comprise an N+ epitaxial layer 410 formed upon a P-type substrate 102. The anode may comprise an active region 502 of the P-substrate. Contacts 804, 806 to the cathode and anode may be formed through the BOX layer 202. Contact to the anode may be accomplished via a deep trench 404 filled with a conductive plug 804. The deep trench 404 may also provide electrical isolation for the cathode (as well as p-n junction 808). Advantageously, embodiments of the present invention may be formed during formation of other structures which also include deep trenches (for example, deep trench capacitors) in order to reduce process steps required to form the diode under the BOX layer of the SOI substrate.

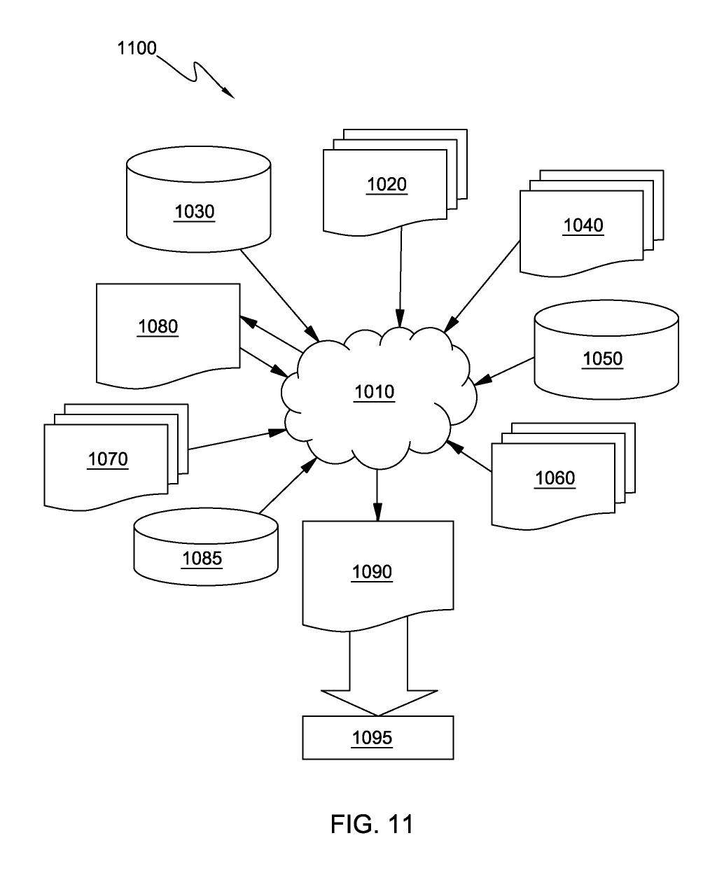

FIG. 11 shows a block diagram of an exemplary design flow 1100 used for example, in semiconductor IC logic design, simulation, test, layout, and manufacture. Design flow 1100 includes processes, machines and/or mechanisms for processing design structures or devices to generate logically or otherwise functionally equivalent representations of the design structures and/or devices described above and shown in FIGS. 1-10. The design structures processed and/or generated by design flow 1100 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 1100 may vary depending on the type of representation being designed. For example, a design flow 1100 for building an application specific IC (ASIC) may differ from a design flow 1100 for designing a standard component or from a design flow 1100 for instantiating the design into a programmable array, for example a programmable gate array (PGA) or a field programmable gate array (FPGA) offered by Altera® Inc. or Xilinx® Inc.

FIG. 11 illustrates multiple such design structures including an input design structure 1020 that is preferably processed by a design process 1010. Design structure 1020 may be a logical simulation design structure generated and processed by design process 1010 to produce a logically equivalent functional representation of a hardware device. Design structure 1020 may also or alternatively comprise data and/or program instructions that when processed by design process 1010, generate a functional representation of the physical structure of a hardware device. Whether representing functional and/or structural design features, design structure 1020 may be generated using electronic computer-aided design (ECAD) such as implemented by a core developer/designer. When encoded on a machine-readable data transmission, gate array, or storage medium, design structure 1020 may be accessed and processed by one or more hardware and/or software modules within design process 1010 to simulate or otherwise functionally represent an electronic component, circuit, electronic or logic module, apparatus, device, or system such as those shown in FIGS. 1-10. As such, design structure 1020 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 1010 preferably employs and incorporates hardware and/or software modules for synthesizing, translating, or otherwise processing a design/simulation functional equivalent of the components, circuits, devices, or logic structures shown in FIGS. 1-10 to generate a netlist 1080 which may contain design structures such as design structure 1020. Netlist 1080 may comprise, for example, compiled or otherwise processed data structures representing a list of wires, discrete components, logic gates, control circuits, I/O devices, models, etc. that describes the connections to other elements and circuits in an integrated circuit design. Netlist 1080 may be synthesized using an iterative process in which netlist 1080 is resynthesized one or more times depending on design specifications and parameters for the device. As with other design structure types described herein, netlist 1080 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 1010 may include hardware and software modules for processing a variety of input data structure types including netlist 1080. Such data structure types may reside, for example, within library elements 1030 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 1040, characterization data 1050, verification data 1060, design rules 1070, and test data files 1085 which may include input test patterns, output test results, and other testing information. Design process 1010 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 1010 without deviating from the scope and spirit of the invention. Design process 1010 may also include modules for performing standard circuit design processes such as timing analysis, verification, design rule checking, place and route operations, etc.

Design process 1010 employs and incorporates logic and physical design tools such as HDL compilers and simulation model build tools to process design structure 1020 together with some or all of the depicted supporting data structures along with any additional mechanical design or data (if applicable), to generate a second design structure 1090. Design structure 1090 resides on a storage medium or programmable gate array in a data format used for the exchange of data of mechanical devices and structures (e.g., information stored in a IGES, DXF, Parasolid XT, JT, DRG, or any other suitable format for storing or rendering such mechanical design structures). Similar to design structure 1020, design structure 1090 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-10. In an embodiment, design structure 1090 may comprise a compiled, executable HDL simulation model that functionally simulates the devices shown in FIGS. 1-10.

Design structure 1090 may also employ a data format used for the exchange of layout data of integrated circuits and/or symbolic data format (e.g. information stored in a GDSII (GDS2), GL1, OASIS, map files, or any other suitable format for storing such design data structures). Design structure 1090 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-10. Design structure 1090 may then proceed to a stage 1095 where, for example, design structure 1090 proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A diode structure comprising:
a silicon substrate having a first active region therein, the first active region being doped with a first type of dopant;
an epitaxial layer grown on the silicon substrate having a second active region therein, the second active region being doped with a second type of dopant;
a buried dielectric layer overlying the epitaxial layer having an opening for making a contact with the second active region;
a trench structure formed through the buried dielectric layer, the epitaxial layer, and extends into the underlying silicon substrate, the trench structure surrounds the second active region to define a sidewall boundary of the second active region and the buried dielectric layer defines an upper boundary of the second active region;
a filler structure and a conductive plug positioned in the trench structure; and,
wherein the first active region in contact with the second active region comprises a junction of the diode structure formed below the buried dielectric layer.

2. The diode structure of claim 1, wherein the junction of the diode structure comprises a vertical junction.

3. The diode structure of claim 1, wherein the first type of dopant in the first active region comprises a P-type dopant and the second type of dopant in the second active region comprises an N-type dopant; or wherein the first type of dopant in the first active region comprises an N-type dopant and the second type of dopant in the second active region comprises a P-type dopant.

4. The diode structure of claim 1, wherein a thickness of the epitaxial layer ranges from about 3 to about 5 microns.

5. The diode structure of claim 1, wherein the second active region has a dopant concentration within a range of about 1×10¹⁹ atoms per cm³ to about 1×10²⁰ atoms per cm³.

6. The diode structure of claim 1, wherein the conductive plug comprises conductively doped polysilicon.

7. The diode structure of claim 1, wherein the conductive plug comprises a metal.

8. The diode structure of claim 1, further comprising:
a first contact to the first active region, wherein the first contact is physically coupled to the conductive plug; and
a second contact to the second active region.

9. The diode structure of claim 1, wherein a width of the trench structure ranges between about 90 to about 500 nanometers.

10. The diode structure of claim 1, wherein the junction is formed between a plurality of the trench structures and wherein the plurality of the trench structures are formed in substantially parallel alignment on the silicon substrate.

11. The diode structure of claim 1, further comprising a well region in the silicon substrate around the first active region and below the second active region, the well region being doped with a third type of dopant having the same polarity and a lower dopant concentration than the second type of dopant, wherein the first active region in contact with the well region comprises a lateral junction of the diode structure formed below the buried dielectric layer.

12. A method of forming a diode structure comprising:
providing a silicon-on-insulator (SOI) substrate comprising a silicon substrate, an epitaxial layer overlying the silicon substrate, a buried dielectric layer overlying the epitaxial layer and an upper silicon layer overlying the buried dielectric layer, wherein the epitaxial layer is doped with a second type of dopant, the epitaxial layer doped with the second type of dopant forming a second active region;
forming a trench structure having sidewalls and a bottom, the trench structure extending through the upper silicon layer, the buried dielectric layer, and the epitaxial layer, the bottom of the trench structure located in the underlying silicon substrate, and the trench structure surrounding the second active region to define a sidewall boundary of the second active region and the buried dielectric layer defines an upper boundary of the second active region;
forming a first active region in the silicon substrate within a region bounded by the trench structure and below the second active region;
forming a filler structure on the sidewalls and the bottom of the trench structure; and
filling the trench structure with a conductive plug; and,
wherein the first active region in contact with the second active region comprises a junction of the diode structure formed below the buried dielectric layer.

13. The method of claim 12, wherein the junction of the diode structure comprises a vertical junction.

14. The method of claim 12, wherein the conductive plug comprises conductively doped polysilicon.

15. The method of claim 12, wherein the conductive plug comprises a metal.

16. The method of claim 12, wherein the first type of dopant in the first active region comprises a P-type dopant and the second type of dopant in the second active region comprises an N-type dopant; or wherein the first type of dopant in the first active region comprises an N-type dopant and the second type of dopant in the second active region comprises a P-type dopant

17. The method of claim 12, wherein the filler structure comprises a high-K dielectric layer and a metal layer overlying the high-K dielectric layer on the sidewalls of the trench structure and the metal layer on the bottom of the trench structure.

18. The method of claim 12, further comprising:
forming a first contact to the first active region, wherein the first contact is physically coupled to the conductive plug; and
forming a second contact to the second active region.

19. The method of claim 12, wherein the second active region has a dopant concentration within a range of about 1×10¹⁹ atoms per cm³ to about 1×10²⁰ atoms per cm³.

20. The method of claim 12, further comprising:
forming a third type of dopant in the silicon substrate, the third type of dopant having the same polarity and a lower dopant concentration than the second type of dopant, the third type of dopant in the silicon substrate forming a well region in the silicon substrate below the second active region; and,
forming the first active region in the well region, wherein the first active region in contact with the well region comprises a lateral junction of the diode structure formed below the buried dielectric layer.
